(19) United States
(12) Patent Application Publication
(10) Pub. No.: US 2026/0101763 A1
(43) Pub. Date: Apr. 9, 2026

(54) SEMICONDUCTOR PACKAGE

(71) Applicant: Samsung Electronics Co., Ltd., Suwon-si (KR)

(72) Inventors: Seongmin Son, Suwon-si (KR); Kyuha Lee, Suwon-si (KR); Joohee Jang, Suwon-si (KR)

(21) Appl. No.: 19/193,213

(22) Filed: Apr. 29, 2025

(30) Foreign Application Priority Data
Aug. 27, 2024 (KR) 10-2024-0114867

(51) Int. Cl. H01L 23/00; H01L 23/544; H01L 25/07

(52) U.S. Cl. CPC H10W 46/00; H10W 90/00; H10W 46/301; H10W 72/926; H10W 72/936; H10W 72/9445; H10W 72/957; H10W 72/967; H10W 90/26; H10W 90/297; H10W 90/792

(57) ABSTRACT

The semiconductor package includes a semiconductor chip; a first bonding layer including a first inner bonding layer and a first outer bonding layer sequentially stacked on the semiconductor chip along a vertical direction; first inner bonding pads accommodated in the first inner bonding layer on the bonding region of the substrate, and first inner align key patterns accommodated in the first inner bonding layer on the align key region of the substrate; first outer bonding pads accommodated in the first outer bonding layer on the bonding region of the substrate and first outer align key patterns accommodated in the first outer bonding layer on the bonding region of the substrate; a second bonding layer including a second outer bonding layer and a second inner bonding layer sequentially stacked on the first bonding layer along the vertical direction; and a second semiconductor chip disposed on the second bonding layer.

### CROSS-REFERENCE TO RELATED APPLICATION

This application claims priority under 35 U.S.C. § 119 to Korean Patent Application No. 10-2024-0114867, filed on Aug. 27, 2024, in the Korean Intellectual Property Office (KIPO), the contents of which are herein incorporated by reference in their entirety.

### BACKGROUND

### 1. Field

Example embodiments relate to a semiconductor package. More particularly, example embodiments relate to a semiconductor package including a plurality of stacked chips.

### 2. Description of the Related Art

A multi-chip package has multiple chips stacked on a package substrate, with bonding layers accommodating bonding pads interposed between the chips, which may bond the chips together and provide electrical connections therebetween, and align keys may be utilized to align the package substrate and the chips.

Due to differences in pattern density between an align key region where align keys are disposed and a bonding region where bonding pads are disposed, a step difference may occur between the align key region and the bonding region, which may cause voids to occur within the bonding layer, thereby reducing reliability of the multi-chip package.

### SUMMARY

Example embodiments provide a semiconductor package having enhanced electrical characteristics.

According to example embodiments, there is provided a semiconductor package. The semiconductor package may include a semiconductor chip including a substrate having a bonding region and an align key region; a first bonding layer including a first inner bonding layer and a first outer bonding layer sequentially stacked on the semiconductor chip along a vertical direction perpendicular to an upper surface of the substrate; first inner bonding pads accommodated in the first inner bonding layer on the bonding region of the substrate, and first inner align key patterns accommodated in the first inner bonding layer on the align key region of the substrate; first outer bonding pads accommodated in the first outer bonding layer on the bonding region of the substrate and first outer align key patterns accommodated in the first outer bonding layer on the bonding region of the substrate; a second bonding layer including a second outer bonding layer and a second inner bonding layer sequentially stacked on the first bonding layer along the vertical direction; and a second semiconductor chip disposed on the second bonding layer, wherein the first outer bonding pads are respectively in contact with the first inner bonding pads, wherein a first pattern density, which is a ratio of a total planar area of the first inner bonding pads to a planar area of the portion of the first inner bonding layer that is disposed on the bonding region of the substrate, is smaller than a second pattern density, which is a ratio of a total planar area of the first inner align key patterns to a planar area of the portion of the first inner bonding layer that is disposed on the align key region of the substrate, and wherein a third pattern density, which is a ratio of a total planar area of the first outer bonding pads to a planar area of the portion of the first outer bonding layer that is disposed on the bonding region of the substrate, is greater than a fourth pattern density, which is a ratio of a total planar area of the first outer align key patterns to a planar area of the portion of the first outer bonding layer that is disposed on the align key region of the substrate.

According to example embodiments, there is provided a semiconductor package. The semiconductor package may include a first semiconductor chip including a first substrate including a bonding region and an align key region; a first bonding layer including a first inner bonding layer and a first outer bonding layer sequentially stacked on the first semiconductor chip along a vertical direction perpendicular to an upper surface of the first substrate; a second bonding layer disposed on the first bonding layer; and a second semiconductor chip disposed on the second bonding layer and including a second substrate, wherein a first thickness in the vertical direction of the first inner bonding layer on the bonding region of the first substrate is greater than a second thickness in the vertical direction of the first inner bonding layer on the align key region of the first substrate, and wherein a third thickness in the vertical direction of the first outer bonding layer on the bonding region of the first substrate is smaller than a fourth thickness in the vertical direction of the first outer bonding layer on the align key region of the first substrate.

According to example embodiments, there is provided a semiconductor package. The semiconductor package may include a buffer die including a substrate having a bonding region and an align key region; memory dies sequentially stacked on the buffer die; a first bonding layer structure interposed between the buffer die and a lowermost one of the memory dies; and a second bonding layer structure interposed between the memory dies. The first bonding layer structure includes: a first bonding layer including a first inner bonding layer and a first outer bonding layer sequentially stacked on an upper surface of the substrate; first inner bonding pads accommodated in the first inner bonding layer on the bonding region of the substrate; first inner align key patterns accommodated in the first inner bonding layer on the align key region of the substrate; first outer bonding pads accommodated in the first outer bonding layer on the bonding region of the substrate and respectively in contact with the first inner bonding pads; and first outer align key patterns accommodated in the first outer bonding layer on the align key region of the substrate. A first pattern density, which is a ratio of a total planar area of the first inner bonding pads to a planar area of the portion of the first inner bonding layer that is on the bonding region of the substrate, is smaller than a second pattern density, which is a ratio of a total planar area of the first inner align key patterns to a planar area of the portion of the first inner bonding layer that is on the align key region of the substrate, and a third pattern density, which is a ratio of a total planar area of the first outer bonding pads to a planar area of the portion of the first outer bonding layer that is on the bonding region of the substrate, is greater than a fourth pattern density, which is a ratio of a total planar area of the first outer align key patterns to a planar area of the portion of the first outer bonding layer that is on the align key region of the substrate.

The semiconductor package in accordance with example embodiments may include a plurality of semiconductor chips that may be stacked in a vertical direction and bonded with each other by a bonding layer structure. Since no voids may remain in the bonding layer structure, the semiconductor chips may be well bonded with each other, thereby improving electrical characteristics of the semiconductor package.

### BRIEF DESCRIPTION OF THE DRAWINGS

FIG. 1 is a cross-sectional view illustrating a semiconductor package in accordance with example embodiments.

FIG. 2 is a plan view of a semiconductor package in accordance with example embodiments.

FIG. 3 is a cross-sectional view illustrating a semiconductor package in accordance with example embodiments.

FIG. 4, and 6 are plan views illustrating a method of manufacturing a semiconductor package in accordance with example embodiments.

FIGS. 5 and 7-13 are cross-sectional views illustrating a method of manufacturing a semiconductor package in accordance with example embodiments.

FIG. 14 is a cross-sectional view illustrating a semiconductor package in accordance with example embodiments, corresponding to FIG. 3.

FIGS. 15 and 16 are a cross-sectional view and a plan view illustrating a semiconductor package in accordance with example embodiments. FIG. 15 corresponds to FIG. 3.

FIGS. 17 and 18 are plan views illustrating a semiconductor package in accordance with example embodiments.

FIG. 19 is a cross-sectional view illustrating an electronic device in accordance with example embodiments.

### DETAILED DESCRIPTION OF EXAMPLE EMBODIMENTS

Hereinafter, the present disclosure will be explained in detail with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially”may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Hereinafter, a direction parallel to or substantially parallel to an upper surface of a wafer or a substrate may be referred to as a horizontal direction, and a direction perpendicular to or substantially perpendicular to the upper surface of the wafer or the substrate may be referred to as a vertical direction.

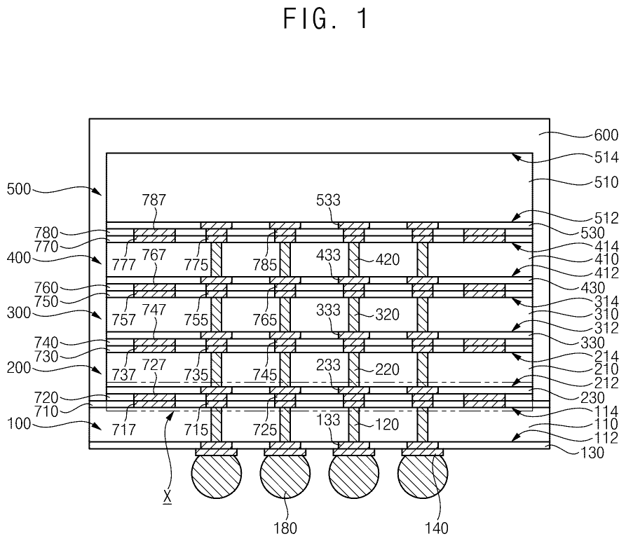

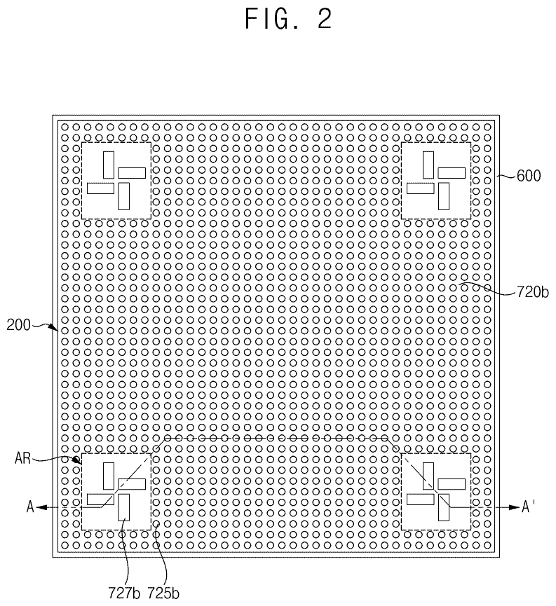

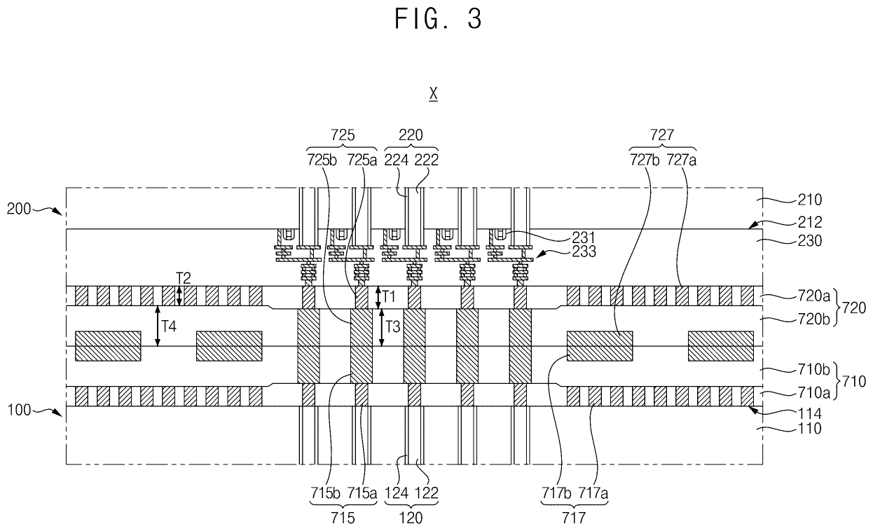

FIGS. 1 to 3 are cross-sectional views and a plan view illustrating a semiconductor package in accordance with example embodiments. FIG. 1 is a cross-sectional view, FIG. 2 is a plan view illustrating structures disposed on a front side of the second semiconductor chip of FIG. 1, and FIG. 3 is an enlarged cross-sectional view of region X of FIG. 1.

Referring to FIGS. 1 to 3, the semiconductor package may include a first semiconductor chip 100, second to fifth semiconductor chips 200, 300, 400 and 500 sequentially stacked on the first semiconductor chip 100, first to fourth bonding layer structures between neighboring ones of the first to fifth semiconductor chips 100, 200, 300, 400 and 500, a mold 600 on the first semiconductor chip 100 and covering sidewalls of the second to fifth semiconductor chips 200, 300, 400 and 500 and an upper surface of the fifth semiconductor chip 500, and first conductive connection members 180 under the first semiconductor chip 100.

The semiconductor package may include a bonding region and an align key region AR, which may include a portion of each of a substrate and the first to fifth semiconductor chips 100, 200, 300, 400 and 500 and the first to fourth bonding layer structures interposed therebetween. In example embodiments, align key regions AR may be spaced apart from each other in the horizontal direction. In the drawings, the align key regions AR are shown to be disposed adjacent to corners of the semiconductor package, e.g., corners of the second semiconductor chip 200; however, the concept of the present invention is not limited thereto and may be arranged in various layouts.

In example embodiments, the first semiconductor chip 100 may be a buffer die, and may include a logic device, e.g., a controller, and each of the second to fifth semiconductor chips 200, 300, 400 and 500 may include a volatile memory device, e.g., DRAM device, SRAM device, etc., or a non-volatile memory device, e.g., flash memory device, EEPROM device, etc. In some examples, the second to fourth semiconductor chips 200, 300 and 400 may collectively form a middle core die, and the fifth semiconductor chip 500 may form a top core die.

Items described in the singular herein may be provided in plural, as can be seen, for example, in the drawings. Thus, the description of a single item that is provided in plural should be understood to be applicable to the remaining plurality of items unless context indicates otherwise. Furthermore, unless context clearly indicates otherwise, the description of a relationship of a single first element and a single second element is not limited to a one-to-one relationship and may include relationships between a single first element and a plurality of second elements, a plurality of first elements and a single second element, and/or a plurality of first elements and a plurality of second elements.

FIG. 1 shows that the middle core die includes the second to fourth semiconductor chips 200, 300 and 400, however, the inventive concept may not be limited thereto, and the middle core die may include a plurality of semiconductor chips. In example embodiments, the semiconductor package may be a high bandwidth memory (HBM) package.

The first semiconductor chip 100 may include a first substrate 110 having first and second surfaces 112 and 114 on opposite sides of the semiconductor chip in the vertical direction, a first through electrode 120 extending through the first substrate 110, a first insulating interlayer 130 beneath the first substrate 110 and covering the first surface 112 of the first substrate 110, and an external connection pad 140 beneath the first insulating interlayer 130.

The first substrate 110 may include a semiconductor material, e.g., silicon, germanium, silicon-germanium, or a III-V group compound semiconductor, e.g., GaP, GaAs, GaSb, etc. In example embodiments, the first substrate 110 may be a silicon-on-insulator (SOI) substrate or a germanium-on-insulator (GOI) substrate.

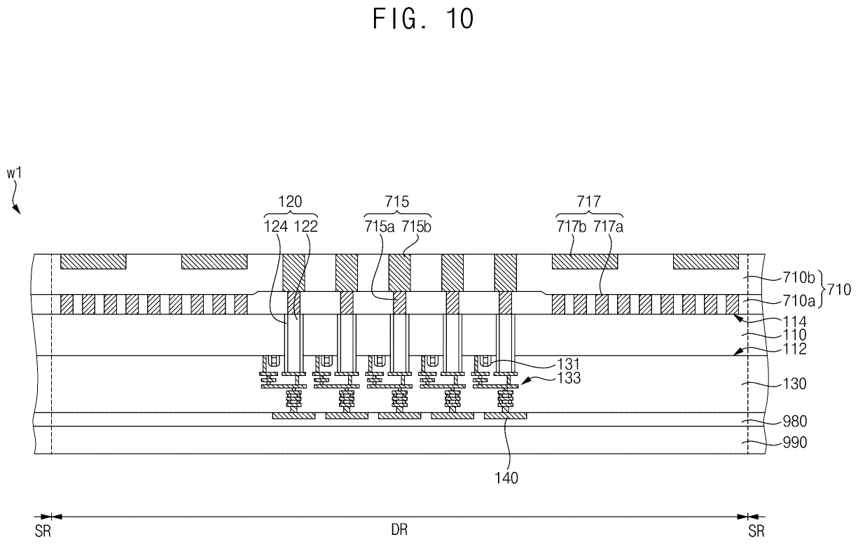

Referring to FIG. 10 together with FIGS. 1 to 3, a circuit device, e.g., a logic device, may be formed beneath the first surface 112 of the first substrate 110. The circuit device may include a plurality of first circuit patterns 131, which may be covered by the first insulating interlayer 130.

The first insulating interlayer 130 may accommodate a first wiring structure 133 therein. The first wiring structure 133 may include, e.g., wirings, vias, contact plugs, etc., however, the first wiring structure 133 is shown as a single structure in FIG. 1 in order to simplify the drawing. The first wiring structure 133 may contact and be electrically connected to the first circuit pattern 131.

The external connection pad 140 may be disposed under the first insulating interlayer 130, and may contact the first wiring structure 133 to be electrically connected thereto. In example embodiments, a plurality of external connection pads 140 may be spaced apart from each other in the horizontal direction.

The first through electrodes 120 may extend through the first substrate 110 in the vertical direction, and a plurality of first through electrodes 120 may be spaced apart from each other in the horizontal direction. The first through electrode 120 may have a geometric shape such as a circle, an ellipse, a polygon, a polygon with rounded corners, etc., in a plan view.

In an example embodiment, the first through electrode 120 may extend through the first substrate 110 and the first insulating interlayer 130 to contact the first wiring structure 133, and may be electrically connected to the external connection pad 140 by the first wiring structure 133. Alternatively, the first through electrode 120 may extend through the first substrate 110 and the first insulating interlayer 130 to contact the external connection pad 140, and may be electrically connected to the external connection pad 140. Alternatively, the first through electrode 120 may extend through the first substrate 110 to contact the first circuit pattern 131 included in the circuit device covered by the first insulating interlayer 130, and may be electrically connected to the external connection pad 140 by the first circuit pattern 131 and the first wiring structure 133.

The external connection pad 140 may include a metal, e.g., aluminum, copper, nickel, silver, etc., and the first insulating interlayer 130 may include, e.g., silicon oxide or a low-k dielectric material such as an oxide doped with carbon or fluorine.

The first through electrode 120, and the wirings, the vias and the contact plugs included in the first wiring structure 133 may include a conductive material, e.g., a metal, a metal nitride, a metal silicide, etc.

The second semiconductor chip 200 may include a second substrate 210 having first and second surfaces 212 and 214 opposite to each other in the vertical direction, a second through electrode 220 extending through the second substrate 210, a second insulating interlayer 230 beneath the second substrate 210 and covering the first surface 212 of the second substrate 210.

The second substrate 210 may include a semiconductor material, e.g., silicon, germanium, silicon-germanium, or a III-V group compound semiconductor, e.g., GaP, GaAs, GaSb, etc. In example embodiments, the second substrate 210 may be a silicon-on-insulator (SOI) substrate or a germanium-on-insulator (GOI) substrate.

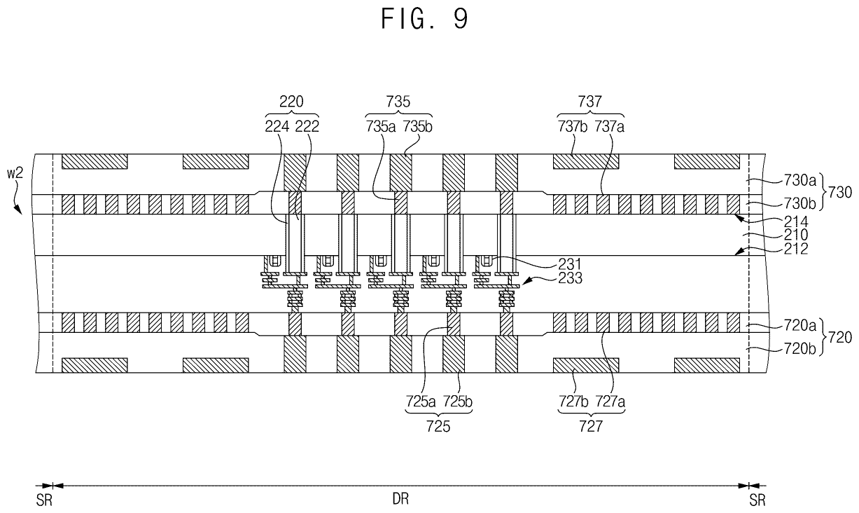

Referring to FIG. 9 together with FIGS. 1 to 3, a circuit device, e.g., a volatile memory device such as DRAM device, SRAM device, etc., or a non-volatile memory device such as flash memory device, EEPROM device, etc., may be formed beneath the first surface 212 of the second substrate 210. The circuit device may include a plurality of second circuit patterns 231, which may be covered by the second insulating interlayer 230.

The second insulating interlayer 230 may accommodate a second wiring structure 233 therein. The second wiring structure 233 may include, e.g., wirings, vias, contact plugs, etc., however, the second wiring structure 233 is shown as a single structure in FIG. 1 in order to avoid the complexity of the drawing. The second wiring structure 233 may contact and be electrically connected to the second circuit pattern 231.

The second through electrode 220 may extend through the second substrate 210 in the vertical direction, and a plurality of second through electrodes 220 may be spaced apart from each other in the horizontal direction. The second through electrode 220 may have a regular geometric shape such a circle, an ellipse, a polygon, a polygon with rounded corners, etc., in a plan view.

In an example embodiment, the second through electrode 220 may extend through the second substrate 210 and the second insulating interlayer 230 to contact the second wiring structure 233. Alternatively, the second through electrode 220 may extend through the second substrate 210 to contact the second circuit pattern 231 included in the circuit device covered by the second insulating interlayer 230, and may be electrically connected to the second wiring structure 233.

The second insulating interlayer 230 may include, e.g., silicon oxide or a low-k dielectric material such as an oxide doped with carbon or fluorine.

The second through electrode 220, and the wirings, the vias and the contact plugs included in the second wiring structure 233 may include a conductive material, e.g., a metal, a metal nitride, a metal silicide, etc.

The first bonding layer structure may bond the first and second semiconductor chips 100 and 200 with each other by a hybrid copper bonding (HCB) process.

The first bonding layer structure may include first and second bonding layers 710 and 720, first and second conductive bonding pads 715 and 725 in the first and second bonding layers 710 and 720, respectively, and first and second align key patterns 717 and 727 in the first and second bonding layers 710 and 720, respectively. In example embodiments, the first and second conductive bonding pads 715 and 725 may contact each other to form a first conductive bonding pad structure, and may respectively contact and be electrically connected to the first through electrode 120 and the second wiring structure 233. In example embodiments, the first and second align key patterns 717 and 727 may form a first align key structure.

In example embodiments, the first conductive bonding pad structure may be disposed in the bonding region of the first bonding layer structure, and the first align key structure may be disposed in the align key region AR of the first bonding layer structure.

The first bonding layer 710 may include a first inner bonding layer 710a and a first outer bonding layer 710b sequentially stacked in the vertical direction on the second surface 114 of the first substrate 110, and the second bonding layer 720 may include a second inner bonding layer 720a and a second outer bonding layer 720b sequentially stacked in the vertical direction below the first surface 212 of the second substrate 210.

The first conductive bonding pad 715 may include a first inner bonding pad 715a and a first outer bonding pad 715b accommodated in the first inner bonding layer 710a and first outer bonding layer 710b respectively, and the second conductive bonding pad 725 may include a second inner bonding pad 725a and a second outer bonding pad 725b accommodated in the second inner bonding layer 720a and second outer bonding layer 720b respectively.

In example embodiments, a plurality of first inner bonding pads 715a may be spaced apart from each other in the horizontal direction, and a plurality of first outer bonding pads 715b may be spaced apart from each other in the horizontal direction. The first outer bonding pads 715b may extend through the first outer bonding layer 710b and respectively contact the first inner bonding pads 715. In example embodiments, a plurality of second inner bonding pads 725a may be spaced apart from each other in the horizontal direction, and a plurality of second outer bonding pads 725b may be spaced apart from each other in the horizontal direction. The second outer bonding pads 725b may extend through the second outer bonding layer 720b and respectively contact the second inner bonding pads 725a.

The first align key pattern 717 may include a first inner align key pattern 717a and a first outer align key pattern 717b accommodated in the first inner bonding layer 710a and the first outer bonding layer 710b respectively, and the second align key pattern 727 may include a second inner align key pattern 727a and a second outer align key pattern 727b accommodated in the second inner bonding layer 720a and the second outer bonding layer 720b respectively.

In example embodiments, a plurality of first inner align key patterns 717a may be spaced apart from each other in the horizontal direction, and a plurality of first outer align key patterns 717b may be spaced apart from each other in the horizontal direction. In the drawings, the first outer align key pattern 717b is shown as not contacting the first inner align key pattern 717a; however, the concept of the present invention is not limited thereto, and the first outer align key pattern 717b may contact the first inner align key pattern 717a by extending through the first outer bonding layer 710b. In example embodiments, a plurality of second inner align key patterns 727a may be spaced apart from each other in the horizontal direction, and a plurality of second outer align key patterns 727b may be spaced apart from each other in the horizontal direction. In the drawings, the second outer align key pattern 727b is shown as not contacting the second inner align key pattern 727a; however, the concept of the present invention is not limited thereto, and the second outer align key pattern 727b may contact the second inner align key pattern 727a by extending through the second outer bonding layer 720b.

The first inner and outer bonding pads 715a and 715b, the first inner and outer align key patterns 717a and 717b, the second inner and outer bonding pads 725a and 725b and the second inner and outer align key patterns 727a and 727b may each have a regular geometric shape such as a circle, an ellipse, a polygon, a polygon with rounded corners, etc., in a plan view.

In the drawings, the second outer align key patterns 727b having, for example, a rectangular shape are arranged radially from a central axis within each of the align key regions AR; however, the concept of the present invention is not limited thereto and may have various layouts. In the drawings, the second outer align key patterns 727b are respectively aligned with the first outer align key patterns 717b in the vertical direction; however, the concept of the present invention is not limited thereto, and the second outer align key patterns 727b may be offset from the first outer align key patterns 717b in the vertical direction. In the drawings, the second outer align key patterns 727b respectively contacts the first outer align key patterns 717b; however, the concept of the present invention is not limited thereto, and the second outer align key patterns 727b may not contact the first outer align key patterns 717b.

In example embodiments, a length of the first inner bonding pad 715a in the vertical direction may be greater than a length of the first inner align key pattern 717a in the vertical direction. Likewise, a length of the second inner bonding pad 725a in the vertical direction may be greater than a length of the second inner align key pattern 727a in the vertical direction.

In example embodiments, a length of the first outer bonding pad 715b in the vertical direction may be greater than a length of the first outer align key pattern 717b in the vertical direction. Likewise, a length of the second outer bonding pad 725b in the vertical direction may be greater than a length of the second outer align key pattern 727b in the vertical direction.

In example embodiments, a width of the first inner bonding pad 715a in the horizontal direction may be substantially the same as or the same as a width of the first inner align key pattern 717a in the horizontal direction, and a width of the first outer bonding pad 715b in the horizontal direction may be smaller than a width of the first outer align key pattern 717b in the horizontal direction. Likewise, a width of the second inner bonding pad 725a in the horizontal direction may be substantially the same as or the same as a width of the second inner align key pattern 727a in the horizontal direction, and a width of the second outer bonding pad 725b in the horizontal direction may be smaller than a width of the second outer align key pattern 727b in the horizontal direction.

Hereinafter, the density, thickness, and vertical distance (e.g., the vertical location or spacing) of the second inner and outer bonding pads 725a and 725b and the second inner and outer align key patterns 727a and 727b will be described. The first inner and outer bonding pads 715a and 715b and the first inner and outer align key patterns 717a and 717b may respectively have the same, substantially the same, or similar density, thickness, and vertical distance as those of the second inner and outer bonding pads 725a and 725b and the second inner and outer align key patterns 727a and 727b, and thus, repeated explanations are omitted herein.

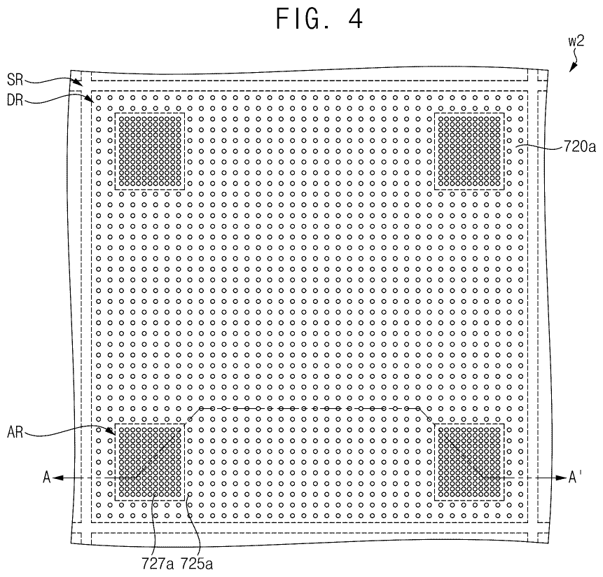

In the present specification, a first pattern density is defined as a ratio of a total planar area of the second inner bonding pads 725a to a planar area of the portion of the second inner bonding layer 720a that is in the bonding region, and a second pattern density is defined as a ratio of a total planar area of the second inner align key patterns 727a to a planar area of the portion of the second inner bonding layer 720a that is in the align key region AR. For example, a planar area may refer to a cross-sectional area in a cross-section parallel to a reference surface of the semiconductor package, such as a lower surface of a base substrate. Referring to FIG. 4, the first pattern density of the second inner bonding pads 725a may be less than the second pattern density of the second inner align key patterns 727a.

A third pattern density is defined as a ratio of a total planar area of the second outer bonding pads 725b to a planar area of the portion of the second outer bonding layer 720b that is in the bonding region, and a fourth pattern density is defined as a ratio of total planar areas of the second outer align key patterns 727b to a planar area of the portion of the second outer bonding layer 720b that is in the align key region AR. Referring to FIG. 6, the third pattern density of the second outer bonding pads 725b may be greater than the fourth pattern density of the second outer align key patterns 727b.

In example embodiments, a first thickness T1 of the second inner bonding layer 720a in the vertical direction in the bonding region may be greater than a second thickness T2 of the second inner bonding layer 720a in the vertical direction in the align key region AR, and accordingly, a first vertical distance from the first surface 212 of the second substrate 210 to a lower surface of the second inner bonding layer 720a in the bonding region may be greater than a second vertical distance from the first surface 212 of the second substrate 210 to a lower surface of the second inner bonding layer 720a in the align key region AR. For example, a step difference may occur in the lower surface of the second inner bonding layer 720a depending on the region.

In example embodiments, a third thickness T3 of the second outer bonding layer 720b in the vertical direction in the bonding region may be less than a fourth thickness T4 of the second outer bonding layer 720b in the vertical direction in the align key region AR.

In example embodiments, a sum of the first thickness T1 and the third thickness T3 may be the same, substantially the same, or similar to a sum of the second thickness T2 and the fourth thickness T4. Accordingly, a third vertical distance from the first surface 212 of the second substrate 210 to a lower surface of the second outer bonding layer 720b in the bonding region may be the same, substantially the same, or similar to a fourth vertical distance from the first surface 212 of the second substrate 210 to a lower surface of the second outer bonding layer 720b in the align key region AR. Accordingly, no step difference may occur or only a relatively small step difference may occur in the lower surface of the second outer bonding layer 720b.

Each of the first inner and outer bonding layers 710a and 710b of the first bonding layer 710 and the second inner and outer bonding layers 720a and 720b of the second bonding layer 720 may include an insulating nitride, e.g., silicon carbonitride, silicon nitride, silicon oxynitride, etc., or an oxide, e.g., silicon oxide. Each of the first inner and outer bonding pads 715a and 715b of the first conductive bonding pad 715, the first inner and outer align key patterns 717a and 717b of the first align key pattern 717, the second inner and outer bonding pads 725a and 725b of the second conductive bonding pad 725, and the second inner and outer align key patterns 727a and 727b of the second align key pattern 727 may include a metal, e.g., copper, aluminum, etc.

In example embodiments, the first inner bonding pad 715a and the first inner align key pattern 717a may include the same or substantially the same material as each other, and the first outer bonding pad 715b and the first outer align key pattern 717b may include the same or substantially the same material as each other. In example embodiments, the first outer bonding pad 715b and the first outer align key pattern 717b may each include copper. In example embodiments, the second inner bonding pad 725a and the second inner align key pattern 727a may include the same or substantially the same materials as each other, and the second outer bonding pad 725b and the second outer align key pattern 727b may include the same or substantially the same materials as each other. In example embodiments, the second outer bonding pad 725b and the second outer align key pattern 727b may each include copper.

The third to fifth semiconductor chips 300, 400 and 500 may be sequentially stacked in the vertical direction on the second semiconductor chip 200.

The third semiconductor chip 300 may include a third substrate 310 having first and second surfaces 312 and 314 on opposite sides of the third semiconductor chip 300 in the vertical direction, a third through electrode 320 extending through the third substrate 310, and a third insulating interlayer 330 beneath the third substrate 310 and covering the first surface 312 of the third substrate 310.

In example embodiments, the third through electrode 320 may extend through the third substrate 310 in the vertical direction, and a plurality of third through electrodes 320 may be spaced apart from each other in the horizontal direction. In example embodiments, the third through electrode 320 may extend through the third substrate 310 and the third insulating interlayer 330 and contact a third wiring structure 333.

The fourth semiconductor chip 400 may include a fourth substrate 410 having first and second surfaces 412 and 414 on opposite sides of the fourth semiconductor chip 400 in the vertical direction, a fourth through electrode 420 extending through the fourth substrate 410, and a fourth insulating interlayer 430 beneath the fourth substrate 410 and covering the first surface 412 of the fourth substrate 410.

In example embodiments, the fourth through electrode 420 may extend through the fourth substrate 410 in the vertical direction, and a plurality of fourth through electrodes 420 may be spaced apart from each other in the horizontal direction. In example embodiments, the fourth through electrode 420 may extend through the fourth substrate 410 and the fourth insulating interlayer 430 and contact a fourth wiring structure 433.

The fifth semiconductor chip 500 may include a fifth substrate 510 having first and second surfaces 512 and 514 on opposite sides of the fifth semiconductor chip 500 in the vertical direction and a fifth insulating interlayer 530 beneath the fifth substrate 510 and covering the first surface 512 of the fifth substrate 510.

Each of the third to fifth substrates 310, 410 and 510 may include a semiconductor material, e.g., silicon, germanium, silicon-germanium, or a III-V group compound semiconductor, e.g., GaP, GaAs, GaSb, etc. In example embodiments, each of the third to fifth substrates 310, 410 and 510 may be a silicon-on-insulator (SOI) substrate or a germanium-on-insulator (GOI) substrate.

A circuit device such as a volatile memory device, e.g., DRAM device, SRAM device, etc., or a non-volatile memory device, e.g., flash memory device, EEPROM device, etc. may be disposed beneath each of the first surfaces 312, 412 and 512 of the third to fifth substrates 310, 410 and 510. The circuit device may include circuit patterns, which may be covered by the third, fourth and fifth insulating interlayers 330, 430 and 530.

Like the first bonding layer structure that may bond the first and second semiconductor chips 100 and 200 with each other by an HCB process, the second to fourth bonding layer structures may respectively bond the second to fifth semiconductor chips 200, 300, 400 and 500 by an HCB process.

For example, the second bonding layer structure may include third and fourth bonding layers 730 and 740, third and fourth conductive bonding pads 735 and 745 accommodated in the third and fourth bonding layers 730 and 740, respectively, and the third and fourth align key patterns 737 and 747 accommodated in the third and fourth bonding layers 730 and 740 respectively. In example embodiments, the third and fourth conductive bonding pads 735 and 745 may contact each other and form a second conductive bonding pad structure, and may respectively contact the second through electrode 120 and the third wiring structure 333. The third and fourth align key patterns 737 and 747 may form a second align key structure.

Additionally, the third bonding layer structure may include fifth and sixth bonding layers 750 and 760, fifth and sixth conductive bonding pads 755 and 765 accommodated in the fifth and sixth bonding layers 750 and 760, respectively, and the fifth and sixth align key patterns 757 and 767 accommodated in the fifth and sixth bonding layers 750 and 760 respectively. In example embodiments, the fifth and sixth conductive bonding pads 755 and 765 may contact each other and form a third conductive bonding pad structure, and may respectively contact the third through electrode 320 and the fourth wiring structure 433. The fifth and sixth align key patterns 757 and 767 may form a third align key structure.

Additionally, the fourth bonding layer structure may include seventh and eighth bonding layers 770 and 780, seventh and eighth conductive bonding pads 775 and 785 accommodated in the seventh and eighth bonding layers 770 and 780, respectively, and the seventh and eighth align key patterns 777 and 787 accommodated in the seventh and eighth bonding layers 770 and 780 respectively. In example embodiments, the seventh and eighth conductive bonding pads 775 and 785 may contact each other and form a fourth conductive bonding pad structure, and may respectively contact the fourth through electrode 420 and a fifth wiring structure 533. The seventh and eighth align key patterns 777 and 787 may form a fifth align key structure.

The first to fifth semiconductor chips 100, 200, 300, 400 and 500 may be electrically connected to each other by the first to fourth through electrodes 120, 220, 320 and 420 respectively extending through the first to fourth substrates 110, 210, 310 and 410, the first to fifth wiring structures 133, 233, 333, 433 and 533 electrically connected to the first to fourth through electrodes 120, 220, 320 and 420, and the first to eighth conductive bonding pads 715, 725, 735, 745, 755, 765, 775 and 785 included in the first to fourth bonding layer structures that may bond the first to fifth semiconductor chips 100, 200, 300, 400 and 500 with each other, and electrical signals, e.g., data signals, control signals, etc., may be transferred to each other.

The mold 600 may be disposed on the first semiconductor chip 100 and cover sidewalls of the second to fourth semiconductor chips 200, 300 and 400 and an upper surface of the fifth semiconductor chip 500. In example embodiments, the mold 600 may include, for example, an Epoxy Molding Compound (EMC).

The first conductive connection member 180 may contact a lower surface of the external connection pad 140 of the first semiconductor chip 100. The first conductive connection member 180 may be a conductive bump such as a solder bump or solder ball.

Conventionally, during manufacturing of the semiconductor package, when there is a pattern density difference between the second outer bonding pads and the second outer align key patterns, a step difference may occur in the upper surface of the second outer bonding layer depending on the region. However, in example embodiments, by additionally forming the second inner bonding layer 720a accommodating the second inner bonding pads 725a and the second inner align key patterns 727a having different pattern densities less than that of the second outer bonding layer 720b, the step difference of the second outer bonding layer 720b may be compensated, and therefore, reliability of the semiconductor package may be improved.

Hereinafter, a method for manufacturing the semiconductor package illustrated in FIGS. 1 to 3 will be described.

FIGS. 4 to 13 are plan views and cross-sectional views illustrating a method of manufacturing a semiconductor package in accordance with example embodiments.

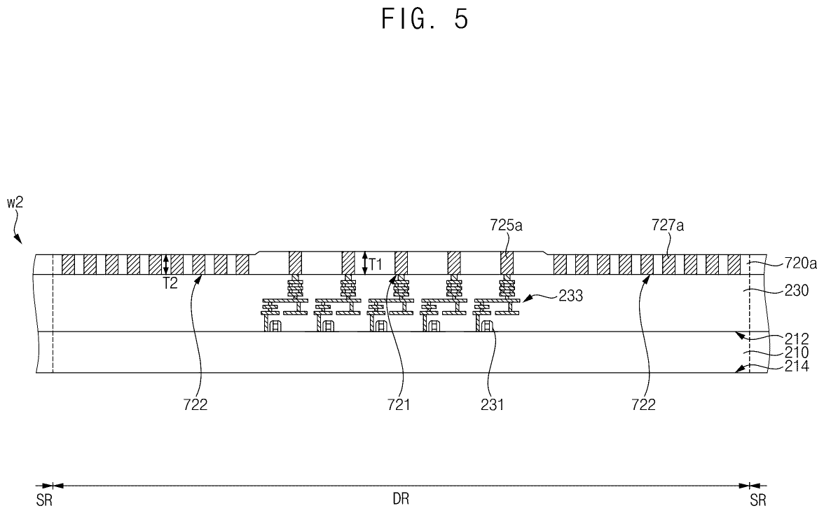

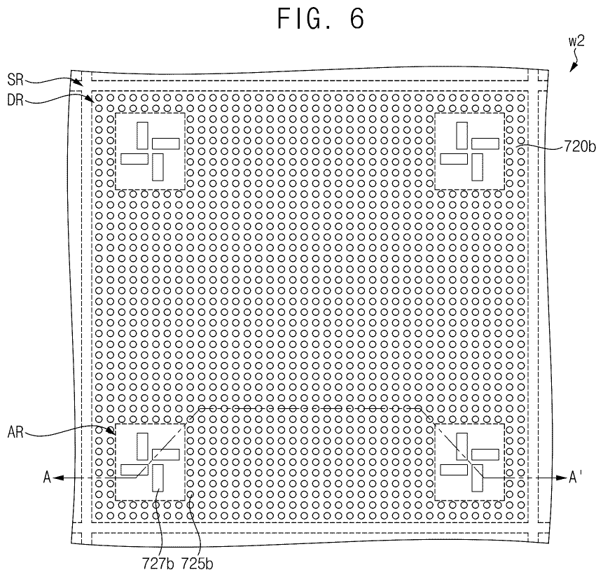

Referring to FIGS. 4 and 5, a second wafer W2 may be provided.

In example embodiments, the second wafer W2 may include a second substrate 210 having first and second surfaces 212 and 214 on opposite sides of the second substrate 210 in the vertical direction. Additionally, the second wafer W2 may include a plurality of die regions DR and a scribe lane region SR surrounding each of the die regions DR. The second wafer W2 may be cut along the scribe lane region SR by a subsequent sawing process to be individualized into a plurality of second semiconductor chips.

In the die region DR, a circuit device may be formed on the first surface 212 of the second substrate 210. The circuit device may include a memory device. The circuit device may include a plurality of second circuit patterns 231, and a second insulating interlayer 230 may be formed on the first surface 212 of the second substrate 210 to cover the second circuit patterns 231.

The second insulating interlayer 230 may accommodate a second wiring structure 233 therein. The second wiring structure 233 may include, e.g., wirings, vias, contact plugs, etc., however, the second wiring structure 233 is shown as a single structure in FIG. 2 in order to avoid the complexity of the drawing. The second wiring structure 233 may contact and be electrically connected to the second circuit pattern 231.

A second inner bonding layer 720a may be formed on the second insulating interlayer 230 and the second wiring structure 233, and first and second openings 721 and 722 extending through the second inner bonding layer 720a may be formed. The first opening 721 may be formed to expose a portion of the second wiring structure 233 in a bonding region where a first conductive bonding pad structure will be formed later, and the second opening 722 may be formed to expose an upper surface of the second insulating interlayer 230 in an align key region AR where a first align key pattern structure will be formed later. In example embodiments, a plurality of first openings 721 may be formed to be spaced apart from each other in the horizontal direction, and a plurality of second openings 722 may be formed to be spaced apart from each other in the horizontal direction.

In example embodiments, the first and second openings 721 and 722 may be formed to have the same, substantially the same, or similar widths in the horizontal direction; however, a spacing between adjacent ones of the first openings 721 may be greater than a spacing between adjacent ones of the second openings 722. That is, a density of the second openings 722 in the align key region AR may be greater than a density of the first openings 721 in the bonding region AR.

A first conductive layer may be formed on the second inner bonding layer 720a to fill the first and second openings 721 and 722, and a planarization process may be performed on an upper portion of the first conductive layer until the upper surface of the second inner bonding layer 720a is exposed. Accordingly, the second inner bonding pad 725a and the second inner align key pattern 727a may be formed in the first and second openings 721 and 722, respectively. In example embodiments, the planarization process may include a chemical mechanical polishing (CMP) process.

Since the density of the second openings 722 in the align key region AR is greater than the density of the first openings 721 in the bonding region, and since the first conductive layer formed in the first and second openings 721, 722 is more readily removed by the polishing agent used in the planarization process compared to the second inner bonding layer 720a including an insulating material, during the planarization process, an upper portion of the second inner bonding layer 720a in the align key region AR, where the exposed area is relatively narrow, may be etched deeper in the vertical direction compared to an upper portion of the second inner bonding layer 720a in the bonding region, where the exposed area is relatively wide.

Accordingly, the second inner bonding layer 720a in the bonding region may be formed to have a first thickness T1 in the vertical direction, and the second inner bonding layer 720a in the align key region AR may be formed to have a second thickness T2 less than the first thickness T1 in the vertical direction. For example, based on the first surface 212 of the second substrate 210, a step difference may occur between the upper surface of the second inner bonding layer 720a formed in the bonding region and the upper surface of the second inner bonding layer 720a formed in the align key region AR.

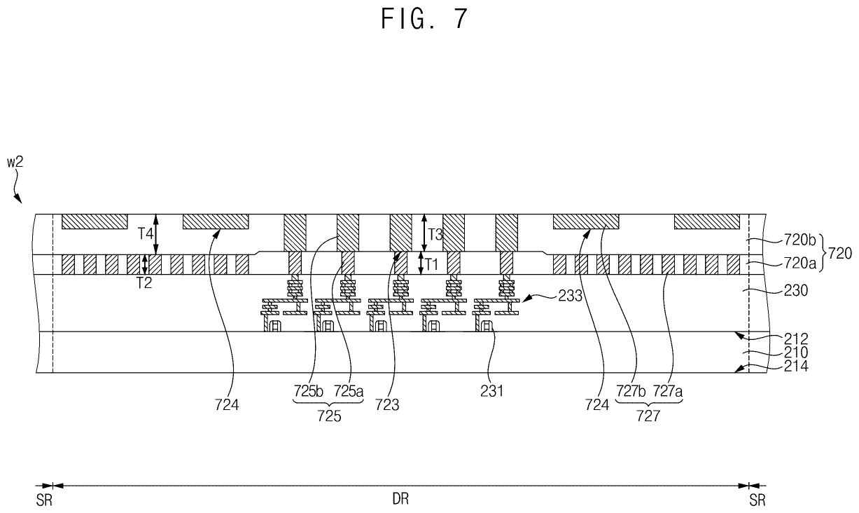

Referring to FIGS. 6 and 7, a second outer bonding layer 720b may be formed on the second inner bonding layer 720a, the second inner bonding pad 725a and the second inner align key pattern 727a, and third and fourth openings 723 and 724 at least partially extending through the second outer bonding layer 720b may be formed. In example embodiments, initially, the second outer 720b may be formed to have a substantially constant thickness in the vertical direction throughout the align key region AR and the bonding region.

The third opening 723 may be formed to expose the second inner bonding pad 725a in the bonding region, and the fourth opening 724 may be formed to at least partially overlap with a portion of the second inner align key patterns 727a in the vertical direction in the align key region AR. In example embodiments, the fourth opening 724 may extend through only an upper portion of the second outer bonding layer 720b without exposing an upper surface of the second inner align key pattern 727a. In example embodiments, a plurality of third openings 723 may be formed to be spaced apart from each other in the horizontal direction, and a plurality of fourth openings 724 may be formed to be spaced apart from each other in the horizontal direction.

Meanwhile, a pattern density of the fourth openings 724 in the align key region AR may be lower than a pattern density of the third openings 723 in the bonding region.

A second conductive layer may be formed on the second outer bonding layer 720b to fill the third and fourth openings 723 and 724, and a planarization process may be performed on an upper portion of the second conductive layer until the upper surface of the second outer bonding layer 720b is exposed. Accordingly, the second outer bonding pad 725b and the second outer align key pattern 727b may be formed in the third and fourth openings 723 and 724, respectively. In example embodiments, the planarization process may include a chemical mechanical polishing (CMP) process.

Since the density of the fourth openings 724 in the align key region AR is lower than the density of the third openings 723 in the bonding region, and since the second conductive layer formed in the third and fourth openings 723 and 724 is more readily removed by the polishing agent used in the planarization process compared to the second outer bonding layer 720b including an insulating material, during the planarization process, an upper portion of the second outer bonding layer 720b in the align key region AR, where the exposed area is relatively wide, is exposed may be etched shallower in the vertical direction compared to an upper portion of the second outer bonding layer 720b in the bonding region, where the exposed area is relatively narrow. Accordingly, after the planarization process, the second outer bonding layer 720b in the bonding region may be formed to have a third thickness T3 in the vertical direction, and the second outer bonding layer 720b in the align key region AR may be formed to have a fourth thickness T4 greater than the third thickness T3 in the vertical direction.

However, as described above, since the first thickness T1 in the vertical direction of the second inner bonding layer 720a in the bonding region is greater than the second thickness T2 in the vertical direction of the second inner bonding layer 720a in the align key region AR, a sum of the first thickness T1 of the second inner bonding layer 720a and the third thickness T3 of the second outer bonding layer 720b in the bonding region may be the same, substantially the same, or similar to a sum of the second thickness T2 of the second inner bonding layer 720a and the fourth thickness T4 of the second outer bonding layer 720b in the align key region AR. For example, unlike the upper surface of the second inner bonding layer 720b, between the upper surface of the second outer bonding layer 720b in the bonding region and the upper surface of the second outer bonding layer 720b in the align key region AR based on the first surface 212 of the second substrate 210, no step difference or only a very small step difference may occur.

The second inner and outer bonding layers 720a and 720b may together form the second bonding layer 720, the second inner and outer bonding pads 725a and 725b may together form the second bonding pad 725, and the second inner and outer align key patterns 727a and 727b may together form the second align key pattern 727.

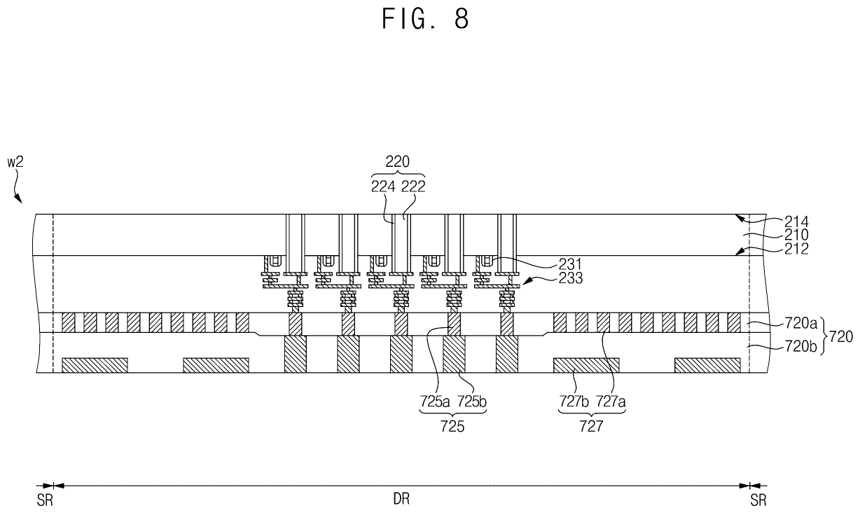

Referring to FIG. 8, after flipping the second wafer W2, a second through electrode 220 extending in the vertical direction through the second substrate 210 may be formed (e.g., the second wafer W2 may be flipped and the second through electrode 220 extending in the vertical direction through the second substrate 210 may be formed.

In an example embodiment, the second through electrode 220 may extend through the second substrate 210 and a portion of the second insulating interlayer 230 to contact the second wiring structure 233.

In example embodiments, a plurality of second through electrodes 220 may be formed to be spaced apart from each other along the horizontal direction.

Referring to FIG. 9, by performing processes the same, substantially the same, or similar to the processes described with reference to FIGS. 4 to 7, a third bonding layer 730, and a third bonding pad 735 and a third align key pattern 737 accommodated in the third bonding layer 730 may be formed.

For example, the third bonding layer 730 may include third inner and outer bonding layers 730a and 730b sequentially stacked in the vertical direction on the second surface 214 of the second substrate 210, the third bonding pad 735 may include third inner and outer bonding pads 735a and 735b accommodated in the third inner and outer bonding layers 730a and 730b respectively, and the third align key pattern 737 may include third inner and outer align key patterns 737a and 737b accommodated in the third inner and outer bonding layers 730a and 730b respectively.

Referring to FIG. 10, a first wafer W1 may be provided.

In example embodiments, the first wafer W1 may include a first substrate 110 having first and second surfaces 112 and 114 on opposite surface of the first wafer W1 in the vertical direction. Additionally, the first wafer W1 may include a plurality of die regions DR and a scribe lane region SR surrounding each of the die regions DR. The first wafer W1 may be cut along the scribe lane region SR by a subsequent sawing process to be individualized into a plurality of first semiconductor chips.

In the die region DR, a circuit device may be formed beneath the first surface 112 of the first substrate 110. The circuit device may include a logic device. The circuit device may include a plurality of first circuit patterns 131, and a first insulating interlayer 130 may be formed beneath the first surface 112 of the first substrate 110 to cover the first circuit patterns 131.

The first insulating interlayer 130 may accommodate a first wiring structure 133 therein. The first wiring structure 133 may include, e.g., wirings, vias, contact plugs, etc., however, the first wiring structure 133 is shown as a single structure in FIG. 10 in order to avoid the complexity of the drawing. The first wiring structure 133 may contact and be electrically connected to the first circuit pattern 131.

Below the first insulating interlayer 130, the external connection pad 140 may be formed to contact and be electrically connected to the first wiring structure 133.

Below the first insulating interlayer 130, a carrier substrate 990 may be bonded via a temporary adhesive layer 980 covering the external connection pad 140. The carrier substrate 990 may include, for example, silicon, glass, plastic, etc., and the temporary adhesive layer 980 may include, for example, glue.

A first through electrode 120 may be formed to extend through the first substrate 110 in the vertical direction. In example embodiments, a plurality of first through electrodes 120 may be formed to be spaced apart from each other along the horizontal direction.

By performing processes that are the same, substantially the same, or similar to the processes described with reference to FIGS. 4 to 7, a first bonding layer 710, and a first bonding pad 715 and a first align key pattern 717 accommodated in the first bonding layer 710 may be formed.

In example embodiments, the first bonding layer 710 may include first inner and outer bonding layers 710a and 710b sequentially stacked in the vertical direction on the second surface 114 of the first substrate 110, the first bonding pad 715 may include first inner and outer bonding pads 715a and 715b accommodated in the first inner and outer bonding layers 710a, 710b respectively, and the first align key pattern 717 may include first inner and outer align key patterns 717a and 717b accommodated in the first inner and outer bonding layers 710a and 710b, respectively.

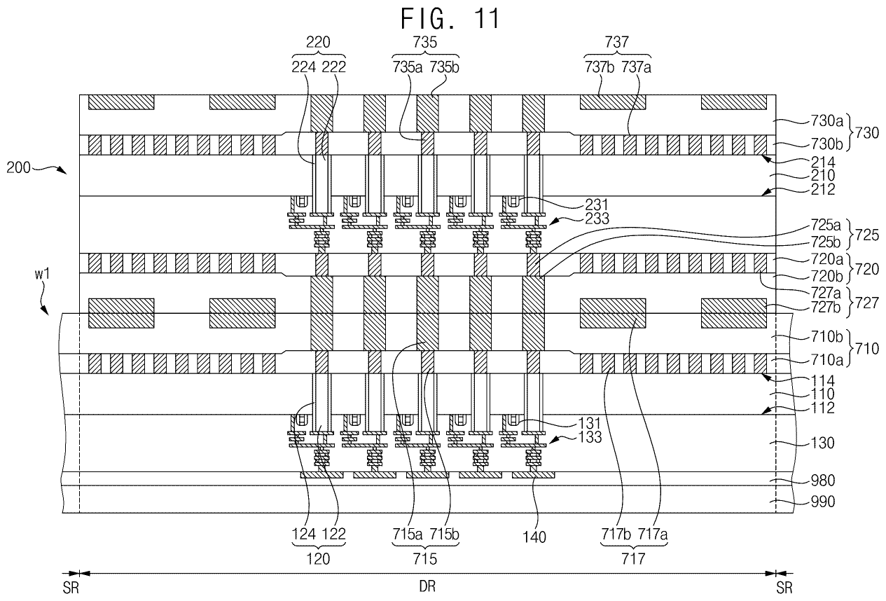

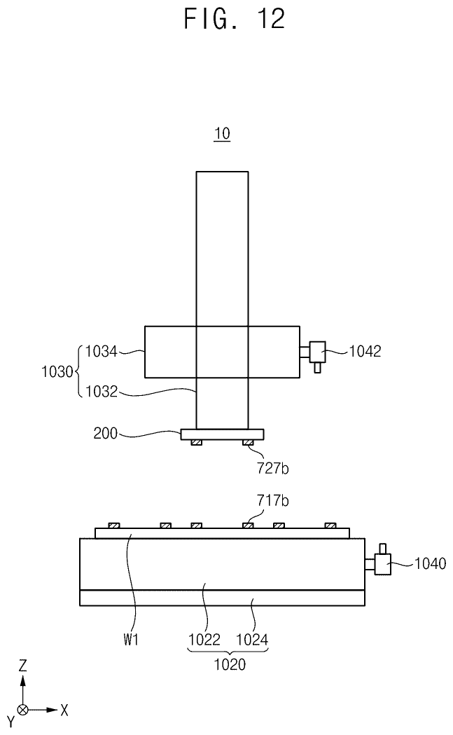

Referring to FIGS. 11 and 12, the second wafer W2 may be individualized into a plurality of second semiconductor chips 200 by cutting along the scribe lane region SR by, for example, a sawing process.

By using, for example, a die bonding apparatus 10, the individualized second semiconductor chips 200 may be picked up and bonded onto the first wafer W1 by a Hybrid Copper Bonding (HCB) method.

The die bonding apparatus 10 may include a lower support structure 1020, an upper support structure 1030 and first and second imaging portions 1040 and 1042. The lower support structure 1020 may include a first stage 1022 for holding a wafer and a first stage driver 1024. The upper support structure 1030 may include a second stage (e.g., a bonding head 1032) for holding a semiconductor chip and a second stage driver (e.g., a bonding head driver 1034). The bonding head driver 1034 may move the bonding head 1032 to pick up the semiconductor chip and bond the picked-up semiconductor chip onto the first wafer W1. The first and second imaging portions 1040 and 1042 may be configured to align the wafer and semiconductor chip.

The bonding head driver 1034 may move the bonding head 1032 to pick up the second semiconductor chip 200.

Subsequently, a first camera of the first imaging portion 1040 may photograph the second outer align key pattern 727b of the second semiconductor chip 200, and a second camera of the second imaging portion 1042 may photograph the first outer align key pattern 717b of the first wafer W1 to measure positions of the second semiconductor chip 200 and the first wafer W1.

Based on the position information of each second semiconductor chip 200 and first wafer W1 measured by the first and second imaging portions 1040 and 1042, alignment may be performed by moving the first stage 1022 and/or the bonding head 1032. In an example embodiment, the bonding head driver 1034 may perform the alignment by moving the bonding head 1032 in X direction, Y direction and Z direction. In other example embodiments, the bonding head driver 1034 may move the bonding head 1032 in Z direction, and the first stage driver 1024 may move the first stage 1022 in X direction and Y direction.

The second semiconductor chips 200 may be mounted on the first wafer W1 by bringing the second bonding layer 720 of each second semiconductor chip 200 into contact with the first bonding layer 710 of the first wafer W1. Each of the second semiconductor chips 200 may be pressed toward the first wafer W1, and lower surfaces of the second conductive bonding pads 725 may contact and bond with upper surfaces of the first conductive bonding pads 715, respectively.

The first and second bonding layers 710 and 720 stacked in the vertical direction and bonded to each other may form a first bonding layer structure together, the first and second conductive bonding pads 715 and 725 stacked in the vertical direction and bonded to each other may form a first conductive bonding pad structure together, and the first and second align key patterns 717 and 727 aligned in the vertical direction may form a first align key structure together.

In example embodiments, the second semiconductor chips 200 may be arranged on the first wafer W1 to correspond to each of the die region DR of the first wafer W1, and the second through electrode 220 of each of the second semiconductor chips 200 may overlap with the first through electrode 120 of the first wafer W1 in the vertical direction.

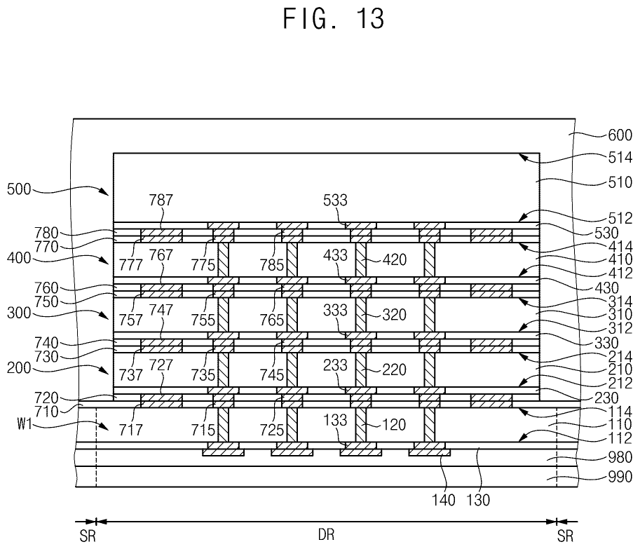

Referring to FIG. 13, the third to fifth semiconductor chips 300, 400 and 500 may be sequentially stacked on the second semiconductor chip 200 and bonded to each other, which may be performed by the HCB method as follows.

After forming individualized third semiconductor chips 300 by performing processes the same, substantially the same, or similar to the processes described with reference to FIGS. 4 to 9 and 11, the third semiconductor chips 300 may be respectively mounted on the second semiconductor chip 200 by bringing the fourth bonding layer 740 on each of the third semiconductor chip 300 into contact with the third bonding layer 730 on each of the second semiconductor chips 200. Each of the third semiconductor chips 300 may be pressed toward each of the second semiconductor chips 200, and lower surfaces of the fourth conductive bonding pads 745 may contact and bond with upper surfaces of the third conductive bonding pads 735, respectively.

The third and fourth bonding layers 730 and 740 stacked in the vertical direction and bonded to each other may form a second bonding layer structure together, the third and fourth conductive bonding pads 735 and 745 stacked in the vertical direction and bonded to each other may form a second conductive bonding pad structure together, and the third and fourth align key patterns 737 and 747 aligned in the vertical direction may form a second align key structure together.

In example embodiments, the third through electrode 320 of each of the third semiconductor chips 300 may overlap with the second through electrode 220 of each of the second semiconductor chips 200 in the vertical direction.

After forming individualized fourth semiconductor chips 400 by performing processes the same, substantially the same, or similar to the processes described with reference to FIGS. 4 to 9 and 11, the fourth semiconductor chips 400 may be respectively mounted on the third semiconductor chip 300 by bringing the sixth bonding layer 760 on each of the fourth semiconductor chip 400 into contact with the fifth bonding layer 750 on each of the third semiconductor chips 300. Each of the fourth semiconductor chips 400 may be pressed toward each of the third semiconductor chips 300, and lower surfaces of the sixth conductive bonding pads 765 may contact and bond with upper surfaces of the fifth conductive bonding pads 755, respectively.

The fifth and sixth bonding layers 750 and 760 stacked in the vertical direction and bonded to each other may form a third bonding layer structure together, the fifth and sixth conductive bonding pads 755 and 765 stacked in the vertical direction and bonded to each other may form a third conductive bonding pad structure together, and the fifth and sixth align key patterns 757 and 767 aligned in the vertical direction may form a third align key structure together.

In example embodiments, the fourth through electrode 420 of each of the fourth semiconductor chips 400 may overlap with the third through electrode 320 of each of the third semiconductor chips 300 in the vertical direction.

After forming individualized fifth semiconductor chips 500 by performing processes the same, substantially the same, or similar to the processes described with reference to FIGS. 4 to 9 and 11, the fifth semiconductor chips 500 may be respectively mounted on the fourth semiconductor chip 400 by bringing the eighth bonding layer 780 on each of the fifth semiconductor chip 500 into contact with the seventh bonding layer 770 on each of the fourth semiconductor chips 400. Each of the fifth semiconductor chips 500 may be pressed toward each of the fourth semiconductor chips 400, and lower surfaces of the eighth conductive bonding pads 785 may contact and bond with upper surfaces of the seventh conductive bonding pads 775, respectively.

The seventh and eighth bonding layers 770 and 780 stacked in the vertical direction and bonded to each other may form a fourth bonding layer structure together, the seventh and eighth conductive bonding pads 775 and 785 stacked in the vertical direction and bonded to each other may form a fourth conductive bonding pad structure together, and the seventh and eighth align key patterns 777 and 787 aligned in the vertical direction may form a fourth align key structure together.

Thereafter, a mold 600 may be formed on the first wafer W1 to fill a space between structures, each of which may include the second to fourth semiconductor chips 200, 300 and 400.

Referring to FIG. 1 again, the first wafer W1 may be cut along the scribe lane region SA by, e.g., a sawing process to be individualized into a plurality of first semiconductor chips 100.

During the sawing process, the mold 600 may also be cut, and may be formed on the first semiconductor chips 100 and cover sidewalls of the second to fifth semiconductor chips 200, 300, 400 and 500 and an upper surface of the fifth semiconductor chips 500.

Subsequently, after removing the carrier substrate 990 and the temporary adhesive layer 980, manufacture of the semiconductor package may be completed by forming a first conductive connection member 180 that contacts the external connection pad 140.

As described above, since the pattern density of the second outer bonding pads 725b may be greater than the pattern density of the second outer align key patterns 727b, during the CMP process for forming the second outer bonding pads 725b and the second outer align key patterns 727b, the third thickness T3 of a portion of the second outer bonding layer 720b accommodating the second outer bonding pads 725b may be formed thinner compared to the fourth thickness T4 of a portion of the second outer bonding layer 720b accommodating the second outer align key patterns 727b.

However, since the pattern density of the second inner bonding pads 725a may be smaller than the pattern density of the second inner align key patterns 727a, the first thickness T1 of a portion of the second inner bonding layer 720a accommodating the second inner bonding pads 725a may be formed to be greater than the second thickness T2 of a portion of the second inner bonding layer 720a accommodating the second inner align key patterns 727a.

Accordingly, as the thickness difference for each region of the second outer bonding layer 720a is compensated for by the second inner bonding layer 720b, the resulting second bonding layer 720 formed by stacking the second inner bonding layer 720a and the second outer bonding layer 720b may be formed with a uniform thickness without thickness difference by region, such that no step difference may be formed on its upper surface. Likewise, the first bonding layer 710 formed by stacking the first inner bonding layer 710a and the first outer bonding layer 710b may also be formed with a uniform thickness without thickness difference by region, such that no step difference may be formed on its upper surface.

Therefore, void formation due to a step difference may be prevented within the first bonding layer structure formed by bonding the first and second bonding layers 710 and 720 to each other.

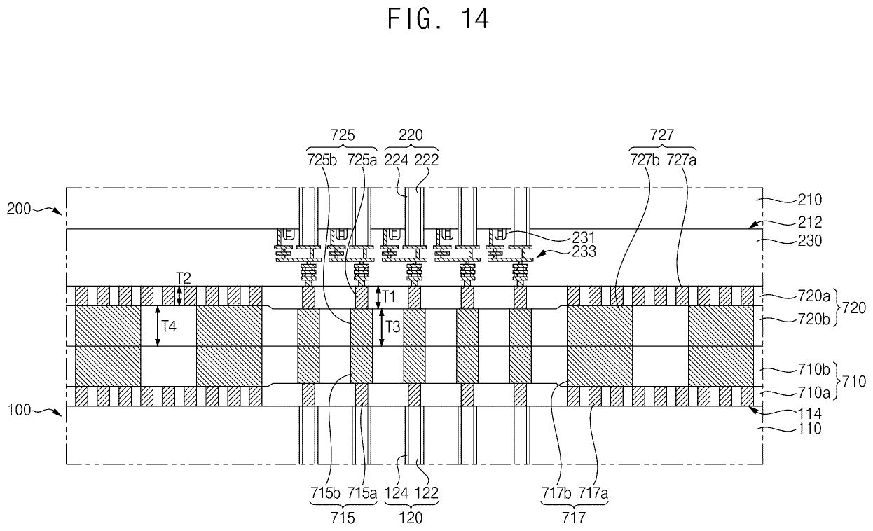

FIG. 14 is a cross-sectional view illustrating a semiconductor package in accordance with example embodiments. The semiconductor packages may be the same, substantially the same as, or similar to that of FIGS. 1 to 3, except the length of the first and second outer align key patterns 717b and 727b in the vertical direction may be different. Thus, repeated explanations may be omitted herein.

Referring to FIG. 14, the length of the first outer align key pattern 717b in the vertical direction may be greater than the length of the first outer bonding pad 715b in the vertical direction. In example embodiments, the first outer align key pattern 717b may extend through the first outer bonding layer 710b and contact some of the first inner align key patterns 717a.

Likewise, the length of the second outer align key pattern 727b in the vertical direction may be greater than the length of the second outer bonding pad 725b in the vertical direction. In example embodiments, the second outer align key pattern 727b may extend through the second outer bonding layer 720b and contact some of the second inner align key patterns 727a.

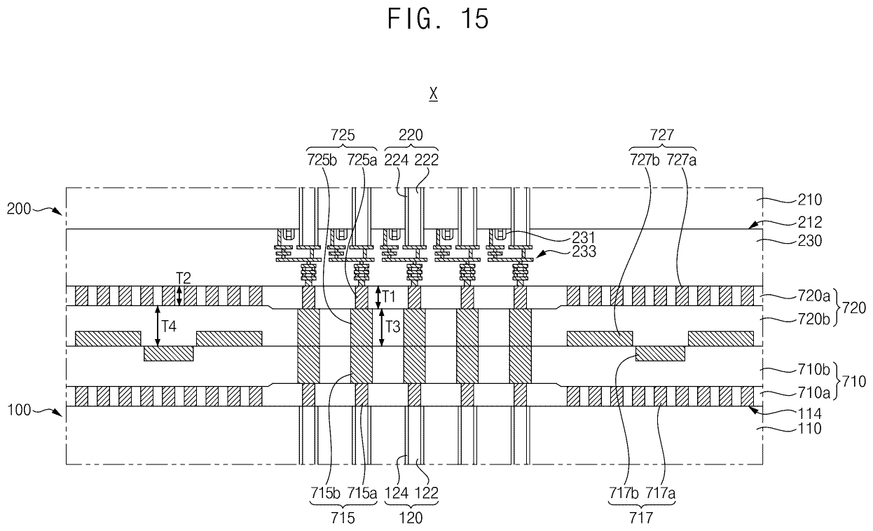

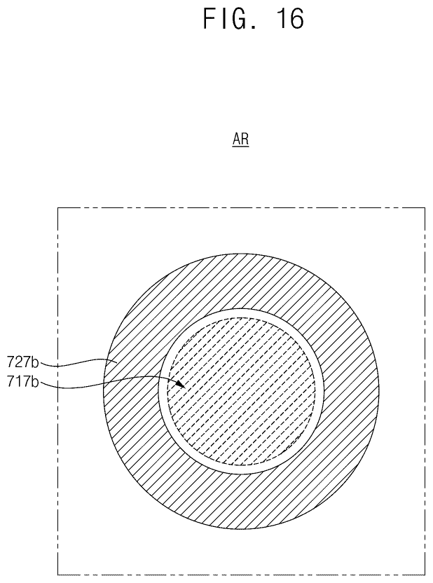

FIGS. 15 and 16 is a cross-sectional view and a plan view illustrating a semiconductor package in accordance with example embodiments. The semiconductor packages may be the same as, substantially the same as, or similar to that of FIGS. 1 to 3, except for the shape and the arrangement of the first and second outer align key patterns 717b and 727b. Thus, repeated explanations may be omitted herein. Meanwhile, FIG. 16 is an enlarged plan view of the align key region AR of a corresponding plan view.

Referring to FIGS. 15 and 16, unlike the semiconductor package described with reference to FIGS. 1 to 3, the second outer align key patterns 727b may not contact the first outer align key patterns 717b.

The first outer align key pattern 717b may have, for example, a circular shape in a plan view, and the second outer align key pattern 727b may have, for example, a ring shape in a plan view, and centroid of the first outer align key pattern 717b and centroid of the second outer align key pattern 727b may be aligned in the vertical direction

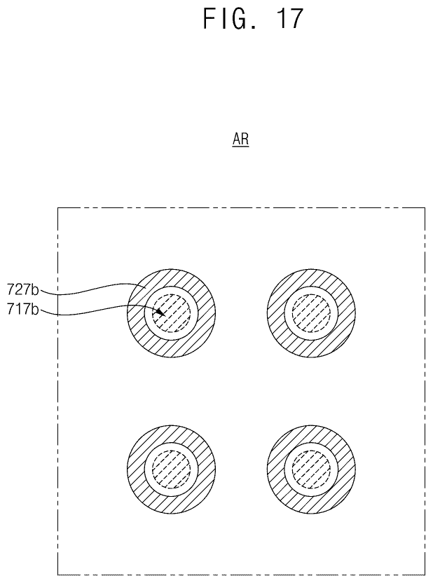

FIG. 17 is a plan view illustrating a semiconductor package in accordance with example embodiments. The semiconductor packages may be the same as, substantially the same as, or similar to that of FIGS. 15 to 16, except for the arrangement of the first and second outer align key patterns 717b and 727b. Thus, repeated explanations may be omitted herein. Meanwhile, FIG. 17 is an enlarged plan view of the align key region AR of a corresponding plan view.

Hereinafter, for convenience of description, the first and second outer align key patterns 717b and 727b will be collectively referred to as an outer align key structure.

Referring to FIG. 17, a plurality of outer align key structures may be spaced apart from each other in the horizontal direction. In the drawings, four of the outer align key structures are shown to be arranged in a grid pattern within the align key region AR; however, the concept of the present invention is not limited thereto, and for example, more than four of the outer align key structures may be arranged in a honeycomb pattern. That is, the outer align key structures may have various layouts.

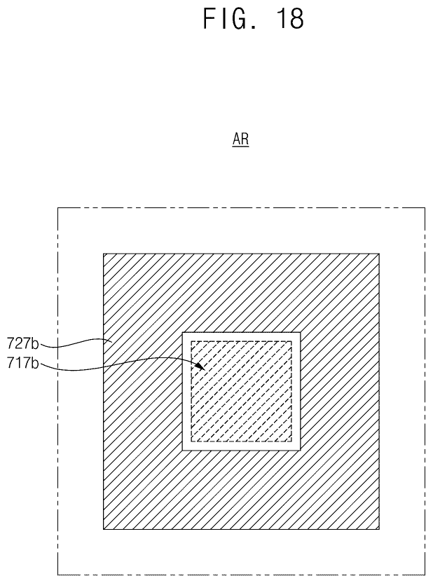

FIG. 18 is a plan view illustrating a semiconductor package in accordance with example embodiments. The semiconductor packages may be the same as, substantially the same as, or similar to that of FIGS. 15 to 16, except for the shape of the first and second outer align key patterns 717b and 727b. Thus, repeated explanations may be omitted herein. Meanwhile, FIG. 18 is an enlarged plan view of the align key region AR of a corresponding plan view.

Hereinafter, for convenience of description, the first and second outer align key patterns 717b and 727b will be collectively referred to as an outer align key structure.

Referring to FIG. 18, the first outer align key pattern 717b may have, for example, a rectangular shape in a plan view, and the second outer align key pattern 727b may have, for example, a rectangular ring shape in a plan view, and the centroid of the first outer align key pattern 717b and the centroid of the second outer align key pattern 727b may be aligned in the vertical direction.

Meanwhile, the shapes of the first and second outer align key patterns 717b and 727b are not limited thereto. That is, the first outer align key pattern 717b may have a shape of, e.g., an ellipse, a polygon, a polygon with rounded corners, etc., in a plan view, and the second outer align key pattern 727b may have a corresponding ring shape. Conversely, the second outer align key pattern 727b may have a shape of, e.g., an ellipse, a polygon, a polygon with rounded corners, etc., in a plan view and the first outer align key pattern 717b may have a corresponding ring shape.

Although the drawings show one outer align key structure within the align key region AR, the concept of the present invention is not limited thereto, and similar to FIG. 17, a plurality of outer align key structures may have various layouts.

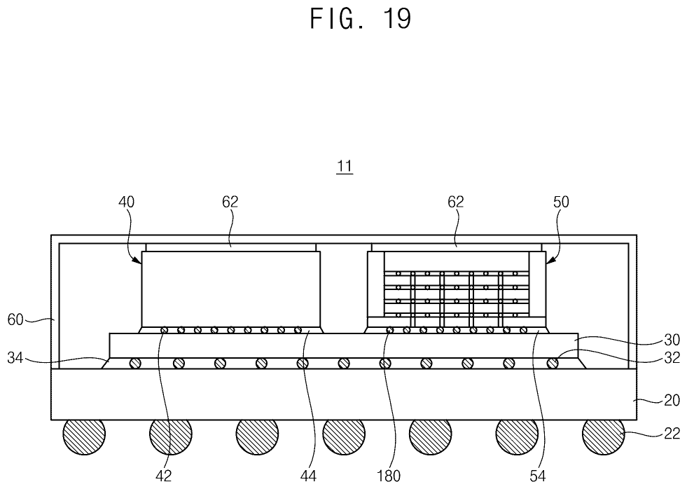

FIG. 19 is a cross-sectional view illustrating an electronic device in accordance with example embodiments. This electronic device may include the semiconductor package shown in FIG. 1 as a second semiconductor device 50. The second semiconductor device 50 may be one of the semiconductor devices described previously.

Referring to FIG. 19, an electronic device 11 may include a package substrate 20, an interposer 30, a first semiconductor device 40 and the second semiconductor device 50. The electronic device 11 may further include first, second and third underfill members 34, 44 and 54, a heat slug 60 and a heat dissipation member 62.

In example embodiments, the electronic device 11 may be a memory module having a 2.5D package structure, and thus may include the interposer 30 for electrically connecting the first and second semiconductor devices 40 and 50 to each other.

In example embodiments, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may be the semiconductor package of FIGS. 1 to 3.

In example embodiments, the package substrate 20 may have an upper surface and a lower surface on opposite sides of the package substrate 20 in the vertical direction. For example, the package substrate 20 may be a printed circuit board (PCB). The printed circuit board may be a multi-layer circuit board having various circuits therein.

The interposer 30 may be mounted on the package substrate 20 through a third conductive connection member 32. In example embodiments, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the third conductive connection member 32. The third conductive connection member 32 may include, e.g., a micro-bump. The silicon interposer may provide a high-density interconnection between the first and second semiconductor devices 40 and 50.

The first semiconductor device 40 may be disposed on the interposer 30. The first semiconductor device 40 may be mounted on and bonded with the interposer 30 by a TCB process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through a fourth conductive connection member 42. For example, the fourth conductive connection member 42 may include, e.g., a micro-bump.

Alternatively, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded with the interposer 30 by a TCB process. In this case, conductive pads of the second semiconductor device 50 may be electrically connected to conductive pads of the interposer 30 by the first conductive connection member 180.

Although a single first semiconductor device 40 and a single second semiconductor device 50 are disposed on the interposer 30, however, the inventive concept may not be limited thereto, and a plurality of first semiconductor devices 40 and/or a plurality of second semiconductor devices 50 may be disposed on the interposer 30.

In example embodiments, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members 34, 44, and 54 may include an adhesive containing an epoxy material.

In example embodiments, a heat slug 60 may cover the package substrate 20 to thermally contact the first and second semiconductor devices 40 and 50. The heat dissipation member 62 may be disposed on an upper surface of each of the first and second semiconductor devices 40 and 50, and may include, e.g., thermal interface material (TIM). The heat slug 60 may thermally contact the first and second semiconductor devices 40 and 50 via the heat dissipation member 62.

A conductive pad may be formed at a lower portion of the package substrate 20, and a second conductive connection member 22 may be disposed beneath the conductive pad. In example embodiments, a plurality of second conductive connection members 22 may be spaced apart from each other in the horizontal direction. The second conductive connection member 22 may be, e.g., a solder ball. The electronic device 11 may be mounted on a module board via the second conductive connection members 22 to form a memory module.

The foregoing is illustrative of example embodiments and is not to be construed as limiting the inventive concept. Although example embodiments have been described, those skilled in the art will readily appreciate that many modifications are possible without materially departing from the novel teachings and advantages of the present invention. Accordingly, all such modifications are intended to be included within the scope of the inventive concept as defined in the claims.

What is claimed is:

1. A semiconductor package comprising:
a semiconductor chip including a substrate having a bonding region and an align key region;
a first bonding layer including a first inner bonding layer and a first outer bonding layer sequentially stacked on the semiconductor chip along a vertical direction with respect to an upper surface of the substrate;
first inner bonding pads accommodated in the first inner bonding layer on the bonding region of the substrate, and first inner align key patterns accommodated in the first inner bonding layer on the align key region of the substrate;
first outer bonding pads accommodated in the first outer bonding layer on the bonding region of the substrate and first outer align key patterns accommodated in the first outer bonding layer on the bonding region of the substrate;
a second bonding layer including a second outer bonding layer and a second inner bonding layer sequentially stacked on the first bonding layer along the vertical direction; and
a second semiconductor chip disposed on the second bonding layer,
wherein the first outer bonding pads are respectively in contact with the first inner bonding pads,
wherein a first pattern density, which is a ratio of a total planar area of the first inner bonding pads to a planar area of the portion of the first inner bonding layer that is disposed on the bonding region of the substrate, is less than a second pattern density, which is a ratio of a total planar area of the first inner align key patterns to a planar area of the portion of the first inner bonding layer that is disposed on the align key region of the substrate, and
wherein a third pattern density, which is a ratio of a total planar area of the first outer bonding pads to a planar area of the portion of the first outer bonding layer that is disposed on the bonding region of the substrate, is greater than a fourth pattern density, which is a ratio of a total planar area of the first outer align key patterns to a planar area of the portion of the first outer bonding layer that is disposed on the align key region of the substrate.

2. The semiconductor package according to claim 1, wherein a first vertical distance from the upper surface of the substrate to upper surfaces of the first inner bonding pads in the vertical direction is greater than a second vertical distance from the upper surface of the substrate to upper surfaces of the first inner align key patterns in the vertical direction, and
wherein a third vertical distance from the upper surface of the substrate to upper surfaces of the first outer bonding pads in the vertical direction is the same as a fourth vertical distance from the upper surface of the substrate to upper surfaces of the first outer align key patterns in the vertical direction.

3. The semiconductor package according to claim 1 wherein a width of each of the first outer bonding pads in a horizontal direction parallel to the upper surface of the substrate is less than a width of each of the first outer align key patterns in the horizontal direction.

4. The semiconductor package according to claim 1, wherein a width of each of the first inner bonding pads in a horizontal direction parallel to the upper surface of the substrate is the same as a width of each of the first inner align key patterns in the horizontal direction.

5. The semiconductor package according to claim 1 wherein a length of each of the first inner bonding pads in the vertical direction is greater than a length of each of the first inner align key patterns in the vertical direction.

6. The semiconductor package according to claim 1, wherein a length of each of the first outer bonding pads in the vertical direction is greater than a length of each of the first outer align key patterns in the vertical direction.

7. The semiconductor package according to claim 1, wherein a length of each of the first outer bonding pads in the vertical direction is smaller than a length of each of the first outer align key patterns in the vertical direction.

8. The semiconductor package according to claim 1, wherein the first inner bonding pads and the first inner align key patterns are formed of a first material, and the first outer bonding pads and the first outer align key patterns are formed of a second material.

9. The semiconductor package according to claim 8, wherein the first outer bonding pads and the first outer align key patterns include copper, and the first inner bonding layer and the first outer bonding layer are formed of silicon carbonitride, silicon nitride, silicon oxynitride, or silicon oxide.

10. The semiconductor package according to claim 1, further comprising:
second outer bonding pads accommodated in the second outer bonding layer on the bonding region of the substrate and respectively in contact with the first outer bonding pads;
second outer align key patterns accommodated in the second outer bonding layer on the align key region of the substrate;
second inner bonding pads accommodated in the second inner bonding layer on the bonding region of the substrate and respectively in contact with the second outer bonding pads; and
second inner align key patterns accommodated in the second inner bonding layer on the align key region of the substrate.

11. A semiconductor package comprising:
a first semiconductor chip including a first substrate including a bonding region and an align key region;
a first bonding layer including a first inner bonding layer and a first outer bonding layer sequentially stacked on the first semiconductor chip along a vertical direction with respect to an upper surface of the first substrate;
a second bonding layer disposed on the first bonding layer; and
a second semiconductor chip disposed on the second bonding layer and including a second substrate,
wherein a first thickness in the vertical direction of the first inner bonding layer on the bonding region of the first substrate is greater than a second thickness in the vertical direction of the first inner bonding layer on the align key region of the first substrate, and
wherein a third thickness in the vertical direction of the first outer bonding layer on the bonding region of the first substrate is smaller than a fourth thickness in the vertical direction of the first outer bonding layer on the align key region of the first substrate.

12. The semiconductor package according to claim 11, wherein the sum of the first thickness and the third thickness is the same as the sum of the second thickness and the fourth thickness.

13. The semiconductor package according to claim 11, wherein the second bonding layer includes a second outer bonding layer and a second inner bonding layer sequentially stacked on the first outer bonding layer along the vertical direction.

14. The semiconductor package according to claim 13, wherein a fifth thickness in the vertical direction of the second outer bonding layer on the bonding region of the first substrate is smaller than a sixth thickness in the vertical direction of the second outer bonding layer on the align key region of the first substrate, and
wherein a seventh thickness in the vertical direction of the second inner bonding layer on the bonding region of the first substrate is greater than an eighth thickness of the second inner bonding layer on the align key region of the first substrate in the vertical direction.

15. The semiconductor package according to claim 14, wherein the sum of the first thickness and the third thickness is the same as the sum of the second thickness and the fourth thickness, and the sum of the fifth thickness and the seventh thickness is the same as the sum of the sixth thickness and the eighth thickness.

16. A semiconductor package comprising
a buffer die including a substrate having a bonding region and an align key region;
memory dies sequentially stacked on the buffer die;
a first bonding layer structure interposed between the buffer die and a lowermost one of the memory dies; and
a second bonding layer structure interposed between the memory dies,
wherein the first bonding layer structure includes:
a first bonding layer including a first inner bonding layer and a first outer bonding layer sequentially stacked on an upper surface of the substrate;
first inner bonding pads accommodated in the first inner bonding layer on the bonding region of the substrate;
first inner align key patterns accommodated in the first inner bonding layer on the align key region of the substrate;
first outer bonding pads accommodated in the first outer bonding layer on the bonding region of the substrate and respectively in contact with the first inner bonding pads; and
first outer align key patterns accommodated in the first outer bonding layer on the align key region of the substrate, and
wherein a first pattern density, which is a ratio of a total planar area of the first inner bonding pads to a planar area of the portion of the first inner bonding layer that is on the bonding region of the substrate, is less than a second pattern density, which is a ratio of a total planar area of the first inner align key patterns to a planar area of a portion of the first inner bonding layer that is on the align key region of the substrate, and
wherein a third pattern density, which is a ratio of a total planar area of the first outer bonding pads to a planar area of the portion of the first outer bonding layer that is on the bonding region of the substrate, is greater than a fourth pattern density, which is a ratio of a total planar area of the first outer align key patterns to a planar area of the portion of the first outer bonding layer that is on the align key region of the substrate.

17. The semiconductor package according to claim 16, wherein the second bonding layer structure includes:
a second bonding layer including a second inner bonding layer and a second outer bonding layer sequentially stacked on a lower surface of the lowermost one of the memory dies;
second inner bonding pads accommodated in the second inner bonding layer on the bonding region of the substrate;
second inner align key patterns accommodated in the second inner bonding layer on the align key region of the substrate;
second outer bonding pads accommodated in the second outer bonding layer on the bonding region of the substrate and respectively in contact with the second inner bonding pads and the first outer bonding pads; and
second outer align key patterns accommodated in the second outer bonding layer on the align key region of the substrate.

18. The semiconductor package of claim 17, wherein a fifth pattern density, which is a ratio of a total planar area of the second inner bonding pads to a planar area of the portion of the second inner bonding layer that is disposed on the bonding region of the substrate, is less than a sixth pattern density, which is a ratio of a total planar area of the second inner align key patterns to a planar area of the portion of the second inner bonding layer that is disposed on the align key region of the substrate, and
wherein a seventh pattern density, which is a ratio of a total planar area of the second outer bonding pads to a planar area of the portion of the second outer bonding layer that is disposed on the bonding region of the substrate, is greater than an eighth pattern density, which is a ratio of a total planar area of the second outer align key patterns to a planar area of the portion of the second outer bonding layer that is disposed on the align key region of the substrate.

19. The semiconductor package according to claim 18, wherein the first inner bonding pads and the first inner align key patterns are formed of a first material, and the first outer bonding pads and the first outer align key patterns include are formed of a second material, and
wherein the second inner bonding pads and the second inner align key patterns are formed of a third material, and the second outer bonding pads and the second outer align key patterns include are formed of a fourth material.

20. The semiconductor package according to claim 19, wherein the first outer bonding pads, the first outer align key patterns, the second outer bonding pads and the second outer align key patterns each include copper.
